(19) United States
(12) Patent Application Publication
(10) Pub. No.: US 2018/0047855 A1
(43) Pub. Date: Feb. 15, 2018

(54) POWER SEMICONDUCTOR ELEMENT AND POWER SEMICONDUCTOR MODULE USING SAME

(71) Applicant: HITACHI, LTD., Chiyoda-ku, Tokyo (JP)

(72) Inventors: Kan YASUI, Tokyo (JP); Hiroyuki MATSUSHIMA, Tokyo (JP); Hiroyuki OKINO, Tokyo (JP)

(21) Appl. No.: 15/558,130

(22) PCT Filed: May 15, 2015
(86) PCT No.: PCT/JP2015/064081

§ 371 Date: Sep. 13, 2017

(51) Int. Cl. H01L 29/872; H01L 29/06; H01L 25/18; H01L 29/16

(52) U.S. Cl. CPC H01L 29/872; H01L 29/1608; H01L 29/0692; H01L 25/18; H01L 29/0634

(57) ABSTRACT

In a Schottky barrier diode comprising silicon carbide: an active region includes a first semiconductor region of a first conductivity type configuring a first Schottky junction having a plurality of linear patterns between a first electrode and the first semiconductor region and a second semiconductor region of a second conductivity type adjacent to the first Schottky junction and connected to the first electrode; at the border of the active region and a periphery region, a second Schottky junction comprising the first electrode and the first semiconductor region and having at least one annular pattern surrounding the linear patterns is provided and the second semiconductor region is adjacent to the second Schottky junction and is connected to the first electrode; and the first and second Schottky junctions are conductive parts and the second semiconductor region is a nonconductive part in a forward bias state.

### TECHNICAL FIELD

The present invention relates to: a power semiconductor element using silicon carbide as a semiconductor material; and a power semiconductor module using the power semiconductor element.

### BACKGROUND ART

In a power converter represented by an inverter, a power semiconductor element is used as a major component having a rectifying function and a switching function. Silicon is the mainstream now as a semiconductor material for a power semiconductor element but silicon carbide (SiC) excellent in physical properties has started to be adopted.

SiC has a dielectric breakdown electric field strength one digit higher than silicon and is suitable for high-voltage applications. Further, the thickness of a semiconductor layer can be reduced for a desired element withstand voltage and hence the resistance of the element can be reduced. Furthermore, SiC has a thermal conductivity three times higher than silicon, hardly loses the properties of a semiconductor even at a high temperature, and hence withstands temperature rise in principle. For those reasons, SiC is suitable for a semiconductor material of a power semiconductor element.

In a switching element and a rectifying element in a power semiconductor module constituting an inverter, the development of an SiC hybrid module in which a silicon diode is replaced with an SiC diode as a free wheeling diode that is a rectifying element precedes. The reasons are that, in the case of a rectifying element: the structure and operation are simple and the development of the element is likely to be advanced in comparison with a switching element; and the advantage of being able to dramatically reduce switching loss is obvious.

As such an SiC hybrid module, in a power semiconductor module of a high-voltage specification described in Patent Literature 1, for example, an arm circuit formed by connecting an IGBT (Insulated Gate Bipolar Transistor) of silicon that is a switching element of a high withstand voltage to an SBD (Schottky Barrier Diode) of SiC that is a free wheeling diode in antiparallel is stored in a case.

In an SBD that is a unipolar element, unlike a PN diode that is a bipolar element, minority carriers are not accumulated in the element. Consequently, a recovery current scarcely flows during the switching operation of an arm circuit and hence switching loss generated in a power semiconductor module can be reduced significantly. In an SBD however, when the thickness of a drift layer is increased in order to increase withstand voltage, resistance increases and hence power loss also increases. In an ordinary SBD of Si in particular, power loss increases excessively and hence it can hardly be applied to a high voltage area. In an SBD of SiC in contrast, a drift layer can be significantly thinner than an SBD of Si and hence it can be applied even to a high voltage region of 600 V to 3.3 kV even though it is a unipolar element.

In an SBD, a leak current in an off-state is likely to be larger than a PN diode. This is because the barrier height of a Schottky junction is lower than the barrier height of a P-N junction. In order to reduce the leak current of an SBD, a JBS (Junction Barrier Controlled Schottky) structure or an MPS (Merged PiN Schottky) structure described in Patent Literature 2 is known, for example.

Meanwhile, a cross section of an SBD of SiC having a simplified structure that is a conventional example is shown in FIG. 4 and a cross section of an SBD of SiC having a JBS structure that is another conventional example is shown in FIG. 5. In FIGS. 4 and 5, Reference numeral 5 represents an SiC substrate of an n⁺-type and Reference numeral 10 represents an n -type SiC epitaxial layer (drift layer) comprising SiC. In the SBD of the JBS structure shown in FIG. 5, a p-type impurity region 2 is formed in an n-type impurity region 1 over the surface of an n⁻-type SiC epitaxial layer 10. In an off-state, a cathode electrode 3 in FIG. 5 takes a positive potential, hence a p-n junction 4 is inversely biased, a depletion layer extending from a junction interface of the p-n junction 4 relaxes the electric field over the surface of a Schottky junction 9, and hence a leak current reduces.

Meanwhile, a junction structure in the MPS structure is similar to the junction structure shown in FIG. 5 and a leak current reduces similarly to a JBS structure. In the MPS structure, however, an impurity concentration in a p-type impurity region 2 is increased and thus the connection of the p-type impurity region 2 and an anode electrode 6 is ohmic contact or close to ohmic contact. As a result, during a forward bias, a minority carrier is injected into an n⁻-type SiC epitaxial layer 10 from the p-type impurity region 2, resistance lowers by conductivity modulation, and hence surge current ruggedness improves.

Meanwhile, in the technology described in Patent Literature 2, in a JBS structure and an MPS structure, a p-type impurity region is formed by combining a p-type impurity element the concentration of which is not less than 1×10¹⁷ cm⁻³ to not more than 1×10²² cm ⁻³ with an n-type impurity element the concentration ratio of which to the p-type impurity element is more than 0.33 to less than 1.0. As a result, contact resistance between an anode electrode and the p-type impurity region reduces and surge current ruggedness improves.

A planar pattern of an SBD of SiC having a JBS structure that is a conventional example is shown in FIG. 6. As shown in FIG. 6, a plurality of linear n-type impurity regions 1 in each of which a Schottky junction is formed are aligned in the longitudinal direction in parallel with each other at equal intervals. That is, the planar pattern of the conventional example is a so-called line-and-space pattern. Here, the n-type impurity regions 1 are a part of an n -type SiC epitaxial layer 10 in FIG. 5. Further, as shown in FIG. 6, the n-type impurity regions 1 are surrounded by a p-type impurity region 2. Since the p-type impurity region 2 is a nonconductive region as stated above, the area of an effective conductive region in an active region including the n-type impurity regions 1 and the p-type impurity region 2 is smaller than the area of the active region to the extent of the area of the p-type impurity region 2. As a result, the resistance increases more than the case of an SBD of a simplified structure in FIG. 4.

A technology of inhibiting such resistance increase is disclosed in Patent Literature 3. A cross section of an SBD of SiC having a JBS structure that is a conventional example to which the technology is applied is shown in FIG. 7. As shown in FIG. 7, the carrier concentration of an n-type impurity region 11 is increased in the vicinity of a p-type impurity region 2 by ion implantation. By such an n-type impurity region 11, namely a current dispersion layer, the resistance of a constricted current path 12 is reduced and the current path can be expanded up to a part right under the p-type impurity region 2. As a result, conduction loss can be reduced to the extent nearly equal to an SBD of a simplified structure in FIG. 4.

### CITATION LIST

### Patent Literature

Patent Literature 1: Japanese Patent No. 4902029

Patent Literature 2: Japanese Patent Application Laid-Open No. 2014-187115

Patent Literature 3: International Publication WO 2011/151901

### SUMMARY OF INVENTION

### Technical Problem

As described above, by an SBD made of SiC (hereunder referred to as “SiC-SBD”), an SBD of a unipolar element excellent in recovery characteristics can be applied up to a high-voltage region, moreover leak current is reduced by the adoption of a JBS structure or an MPS structure, and the usefulness of an SiC-SBD improves. A problem of an SiC-SBD however is that a surge current ruggedness is lower than a silicon-made PN diode (hereunder referred to as “Si-PND”).

A surge current ruggedness: is a flowing current (non-repetitive) at a limit of not breaking down even when an electric current in the forward direction in a diode drastically exceeds a maximum value (rated value) allowed under ordinary operating conditions; and, in an Si-PND, is allowed roughly up to about ten times a rated current. In contrast, the surge current ruggedness of an SiC-SBD is about a half of an Si-PND.

A factor of allowing the surge current ruggedness of an SiC-SBD to be lower than an Si-PND in spite of the fact that SiC is superior to Si in physical properties at a high temperature as stated above is, according to the study by the present inventors, the temperature characteristics of an SiC-SBD and an Si-PND. Under a high temperature, the resistance of an SiC-SBD of a unipolar element increases and power loss increases due to the deterioration of the mobility of SiC and, when the power loss increases, the temperature of the SiC rises and the resistance of the SiC-SBD increases. As a result, in comparison with an Si-PND having an equivalent on-voltage (V_{F}) at room temperature, the V_{F} of the SiC-SBD increases at a high temperature. For example, in an SiC-SBD of 3.3 kV withstand voltage, the resistance of a drift layer part accounting for the most part of the resistance increases in proportion to the 2.5^{th} to 3.0^{th} power of an absolute temperature and V_{F} at 150° C. is about two times V_{F} at room temperature. In an Si-PND in contrast, although the mobility of Si lowers similarly to SiC at a high temperature, a minority carrier increases by temperature rise and hence V_{F} is inhibited from increasing. For example, V_{F} of an Si-PND of 3.3 kV withstand voltage increases even at 150° C. only by about 10% to 20% of V_{F} at room temperature. Because of such difference in the temperature characteristics of V_{F} between an SiC-SBD and an Si-PND, in an SiC-SBD, under a high temperature immediately before breakdown caused by surge current, positive feedback acts strongly between temperature rise and the increase of V_{F} accompanying the temperature rise and the SiC-SBD breaks down by the generation of an excessive power loss. As a result, the surge current ruggedness of an SiC-SBD is lower than the surge current ruggedness of an Si-PND.

The deterioration of surge current ruggedness is significant in an SiC-SBD of a JBS structure shown in FIGS. 5 and 7. In an SiC-SBD of an MPS structure in contrast, since a minority carrier is injected from a p-type impurity region 2 during forward bias, the increase of V_{F} at a high temperature is inhibited and the deterioration of the surge current ruggedness is inhibited. Problems of an MPS structure of SiC however are: conductivity degradation of expanding a crystal defect such as a basal plane dislocation (BPD) by the injection of a minority carrier; and recovery loss during switching caused by the injection of a minority carrier. Further, the technology described in Patent Literature 2 as stated above, namely the technology of improving surge current ruggedness by reducing a contact resistance between an anode electrode and a p-type impurity region, also has problems similar to an MPS structure.

In view of the above situation, the present invention provides: a power semiconductor element that has an SiC-SBD structure and can improve surge current ruggedness without accompanying the generation of conductivity degradation and recovery loss; and a power semiconductor module using the power semiconductor element.

### Solution to Problem

In order to solve the above problems, a power semiconductor element according to the present invention has a Schottky barrier diode comprising silicon carbide, wherein:

the Schottky barrier diode has an active region and a periphery region located around the active region; the active region includes a first electrode, a first semiconductor region of a first conductivity type configuring a first Schottky junction having a plurality of linear patterns between the first electrode and the first semiconductor region, a second semiconductor region of a second conductivity type adjacent to the first Schottky junction and connected to the first electrode, and a second electrode connected to the first semiconductor region; the periphery region includes the first semiconductor region and the second electrode; at the border of the active region and the periphery region, a second Schottky junction comprising the first electrode and the first semiconductor region and having at least one annular pattern surrounding the linear patterns is provided and the second semiconductor region is adjacent to the second Schottky junction and is connected to the first electrode; and the first and second Schottky junctions are conductive parts and the second semiconductor region is a nonconductive part in a forward bias state.

Further, in order to solve the above problems, a power semiconductor module according to the present invention has an arm circuit configured by connecting a semiconductor switching element to a Schottky barrier diode in antiparallel, wherein the Schottky barrier diode is a Schottky barrier diode in a power semiconductor element according to the present invention.

### Advantageous Effects of Invention

The present invention makes it possible to: relax current concentration by a second Schottky junction having an annular pattern at the border of an active region and a periphery region; further suppress recovery current and conductivity degradation by making a second semiconductor region nonconductive; and hence improve the surge current ruggedness of a Schottky barrier diode comprising silicon carbide (SiC-SBD) without accompanying the generation of the conductivity degradation and recovery loss.

Problems, features, and advantages other than those described above will appear from the following description of embodiments.

### BRIEF DESCRIPTION OF DRAWINGS

FIG. 1 shows a planar pattern of a power semiconductor element according to Embodiment 1.

FIG. 2 is an assembly diagram showing a configuration of a power semiconductor module according to Embodiment 2.

FIG. 3 shows a circuit configuration of a power semiconductor module according to Embodiment 2.

FIG. 4 shows a cross section of an SBD of SiC having a simplified structure that is a conventional example.

FIG. 5 shows a cross section of an SBD of SiC having a JBS structure that is a conventional example.

FIG. 6 shows a planar pattern of an SBD of SiC having a JBS structure that is a conventional example.

FIG. 7 shows a cross section of an SBD of SiC having a JBS structure that is a conventional example.

FIG. 8 shows a cross section taken on line A-A′ in FIG. 1.

FIG. 9 is a sectional view schematically showing the aspect of electric current flowing in an SiC-SBD.

FIG. 10 shows an aspect of current concentration in anode-side patterns of an n-type impurity region.

FIG. 11 is a sectional view showing a depletion layer in a JBS structure.

FIG. 12 shows a planar pattern of a power semiconductor element according to Embodiment 3.

FIG. 13 shows a planar pattern of a power semiconductor element according to Embodiment 4.

FIG. 14 shows an example of relationship between the number of annular patterns and a surge current ruggedness.

FIG. 15 shows a planar pattern of a power semiconductor element according to Embodiment 5.

FIG. 16 shows a connecting part of an annular pattern and a linear pattern.

FIG. 17 shows a current/voltage characteristic of an SiC-SBD according to Embodiment 6.

FIG. 18 shows an example of an anode side pattern. FIG. 19 shows a planar pattern of a power semiconductor element according to Embodiment 7.

FIG. 20 shows a planar pattern of a power semiconductor element according to Embodiment 8.

FIG. 21 is a sectional view in the vertical direction of a power semiconductor element according to Embodiment 9.

### DESCRIPTION OF EMBODIMENTS

Embodiments according to the present invention are explained hereunder in reference to drawings. In each of the drawings, an identical reference number shows an identical configuration or a configuration having a similar function. Here, in the following explanations, n⁻, n, and n⁺ mean that the conductivity type of a semiconductor is an n-type and show that the impurity concentrations or the carrier concentrations are relatively high in this order. Further, p⁻, p, and p⁺ mean that the conductivity type of a semiconductor is a p-type and show that the impurity concentrations or the carrier concentrations are relatively high in this order.

### Embodiment 1

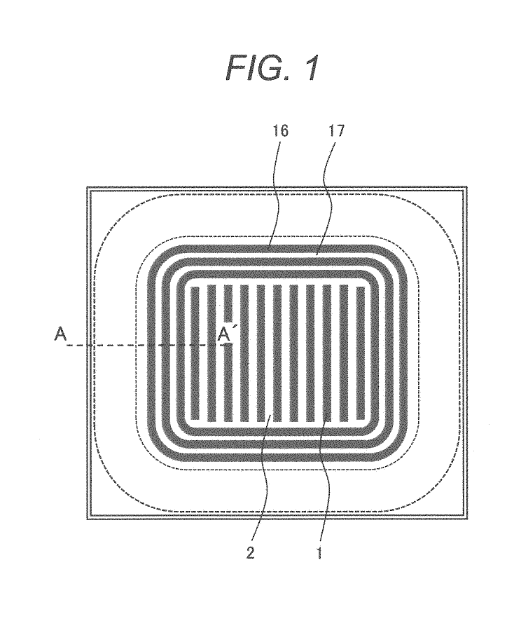

FIG. 1 sows a planar pattern of a power semiconductor element according to Embodiment 1 of the present invention. The power semiconductor element according to Embodiment 1 is an SiC-SBD of a planar type and an n-type having a JBS structure and FIG. 1 shows a planar pattern on an anode side.

As shown in FIG. 1, an SiC-SBD according to the present embodiment has a Schottky junction having a plurality of annular patterns at the border of amain part in an active region where electric current flows and a periphery region that surrounds the active region and secures a desired withstand voltage by relaxing an electric field in an element terminal region in a voltage blocking state. Here, with regard to the two broken lines described in FIG. 1, the region inside the inner broken line is the active region and the region between the two broken lines is the periphery region.

At the main part in the active region, a plurality of linear n-type impurity regions 1 are aligned in the longitudinal direction in parallel with each other at equal intervals. That is, the linear n-type impurity regions 1 constitute a so-called line-and-space pattern over the anode-side principal surface of an SiC-SBD. A Schottky junction is provided between each of the linear n-type impurity regions 1 and an anode electrode not shown in FIG. 1. That is, a plurality of linear Schottky junctions constitute the line-and-space pattern. Further, three concentrically annular n-type impurity regions 16 are formed in the manner of surrounding the n-type impurity regions 1. A Schottky junction is formed between each of the three n-type impurity regions 16 and the anode electrode not shown in FIG. 1. That is, three Schottky junctions having concentrically annular patterns are provided.

Further, a p-type impurity region 2 is provided around the n-type impurity regions 1 in the manner of being in contact with the n-type impurity regions 1. Consequently, the pattern shape of the p-type impurity region 2 is linear similarly to the n-type impurity regions 1 between adjacent two n-type impurity regions 1 and, so to say, a pattern shape of connecting linear patterns at both the ends of each of the linear patterns in the longitudinal direction is formed. In the three concentrically annular n-type impurity regions 16, the n-type impurity region 16 located on the innermost side is in contact with the p-type impurity region 2. Furthermore, a p-type impurity region 17 is provided between adjacent two n-type impurity regions 16 in the manner of being in contact with the n-type impurity regions 16. Consequently, the p-type impurity region 17 also constitutes a concentrically annular pattern similarly to the n-type impurity regions 16. Here, in the three concentrically annular n-type impurity regions 16, the n-type impurity region 16 located on the outermost side is in contact with a p-type impurity region constituting a JTE (Junction Termination Extension) structure as it will be described later in the periphery region.

Meanwhile, in the pattern of the Schottky junction on the anode side in Embodiment 1, concentric annular patterns are added to a line-and-space pattern of a conventional example shown in FIG. 6. Consequently, the linear patterns and the annular patterns are independent patterns separated from each other respectively.

FIG. 8 shows a cross section taken on line A-A′ in FIG. 1.

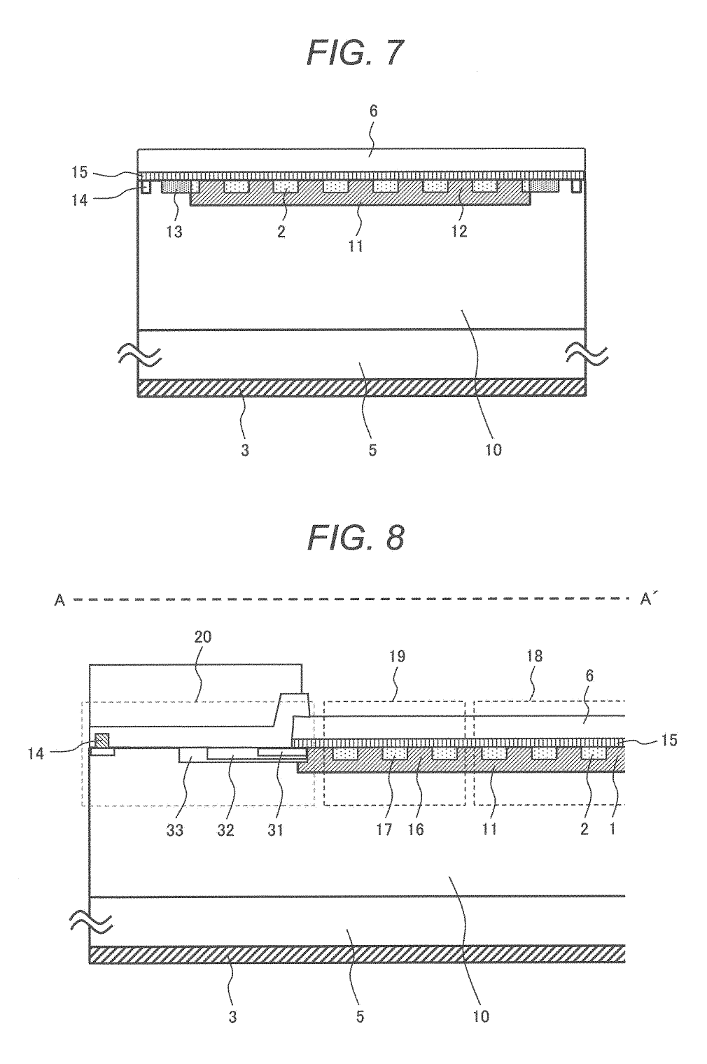

As shown in FIG. 8, an n⁻-type SiC epitaxial layer 10 having an impurity concentration lower than an n⁺-type SiC substrate 5 is in contact with the n⁺-type SiC substrate 5 in the vertical direction. In an active region including a first active region 18 (main part of the active region) having linear patterns and a second active region 19 having annular patterns over an anode-side principal surface, an n-type impurity region 11 having an impurity concentration higher than the n⁻-type SiC epitaxial layer 10 is in contact with the n⁻-type SiC epitaxial layer 10 in the vertical direction. The depth of the n-type impurity region 11 from the anode-side surface, namely the depth of the junction of the n -type epitaxial layer 10 and the n-type impurity region 11, is deeper than the depth of a p-n junction of a p-type impurity region 2, 17 and the n-type impurity region 11. The n-type impurity region 11 corresponds to a current dispersion layer in the aforementioned conventional example (FIG. 7). Consequently, similarly to the conventional example, the resistance of a constricted current path (1, 16) reduces, the region where electric current flows expands in the lateral direction and its resistance reduces, and hence conduction loss can reduce. Here, in the present embodiment, an n-type impurity element in the n-type impurity region 11 is introduced from the exposed surface of the n⁻-type SiC epitaxial layer 10 by ion implantation, for example.

The p-type impurity regions 2 and 17 are located in the n-type impurity region 11, the p-type impurity regions 2 and 17 and the n-type impurity region 11 are in contact with each other, and hence p-n junctions are formed between the p-type impurity regions 2 and 17 and the n-type impurity region 11. Here, in Embodiment 1, the p-type impurity regions 2 and 17 are formed through an identical process. Consequently, the depths of the p-n junctions and the profiles of impurity concentrations in the first active region 18 and the second active region 19 are equivalent.

In the first active region 18, a part of the n-type impurity region 11 extending toward and being exposed to the anode-side surface constitutes the n-type impurity regions 1 having the linear patterns shown in FIG. 1. Further, in the second active region 19, a part of the n-type impurity region 11 extending toward and being exposed to the anode-side principal surface constitutes the n-type impurity regions 16 having the annular patterns shown in FIG. 1.

Over the anode-side principal surface, a Schottky electrode 15 is in contact with the n-type impurity regions 1 and 16 and the p-type impurity regions 2 and 17. As a result, Schottky junction is formed between the n-type impurity regions 1 and 16 and the Schottky electrode 15. Further, an anode electrode 6 is provided over the Schottky electrode 15 in the manner of covering the surface of the Schottky electrode 15. Furthermore, over a cathode-side principal surface, a cathode electrode 3 is in contact with an n⁺-type SiC substrate 5 in the range from the active region (18, 19) to the periphery region 20. Here, the anode electrode 6 acts as a terminal for wiring connection in a power semiconductor module that will be described later or the like. When a forward voltage is applied between the anode electrode 6 and the cathode electrode 3, the Schottky junction is biased forwardly, the n-type impurity regions 1 and 16 act as conductive regions, and the SiC-SBD is in the state where electric current flows forwardly. When a reverse voltage is applied between the anode electrode 6 and the cathode electrode 3 in contrast, the Schottky junction is biased reversely and the SiC-SBD comes to be in a blocking state. On this occasion, a depletion layer extending from the p-n junction between the p-type impurity regions 2 and 17 and the n-type impurity region 11 covers the Schottky junction and hence the electric field at the Schottky junction is relaxed. As a result, leak current reduces and a high voltage is blocked.

In the periphery region 20 outside the second active region 19, a JTE (Junction Termination Extension) structure is configured by p-type impurity regions 31, 32, and 33 at the anode-side surface part of the n⁻-type SiC epitaxial layer 10. The impurity concentrations of the p-type impurity regions 31, 32, and 33 lower in this order. The p-type impurity region 31 is in contact with the n-type impurity region 11 at the outer circumference of the second active region 19. The p-type impurity region 32 is located outside the p-type impurity region 31 and is in contact with the outer circumference of the p-type impurity region 31. The p-type impurity region 33 is located outside the p-type impurity region 32 and is in contact with the outer circumference of the p-type impurity region 32. By such a JTE structure provided around the active region, the electric field at the chip terminal end of an SiC-SBD is relaxed and hence a desired high withstand voltage can be secured. At a chip outer circumference part outside the JTE structure in the periphery region 20, a channel stopper 14 comprising an n⁺-type impurity region provided over the anode-side surface of the n⁻-type SiC epitaxial layer 10 and a floating electrode for equalizing potential in contact with the surface is provided. The JTE structure and the channel stopper have annular patterns over the anode-side principal surface. The surface of the periphery region 20 where electric field intensity increases is protected insulatively by the insulating films.

Meanwhile, the surface of the SiC-SBD in the periphery region 20 is covered with an inorganic insulating film comprising a silicon oxide film and further a surface of the inorganic insulating film is covered with an organic insulating film comprising a polyimide resin, for example.

The improvement of surge current ruggedness by an SiC-SBD according to Embodiment 1 is explained hereunder in comparison with a conventional example.

Forward electric current flows from the anode electrode 6 toward the cathode electrode 3. The outer edge of the anode electrode 6, namely the outer edge of the active region, extends only up to the inside of the periphery region 20 and the area is smaller than the cathode electrode 3. Consequently, the electric current flows toward the cathode electrode 3 while expanding from the border of the active region and the periphery region toward the outer circumference. The situation is the same also in the conventional example.

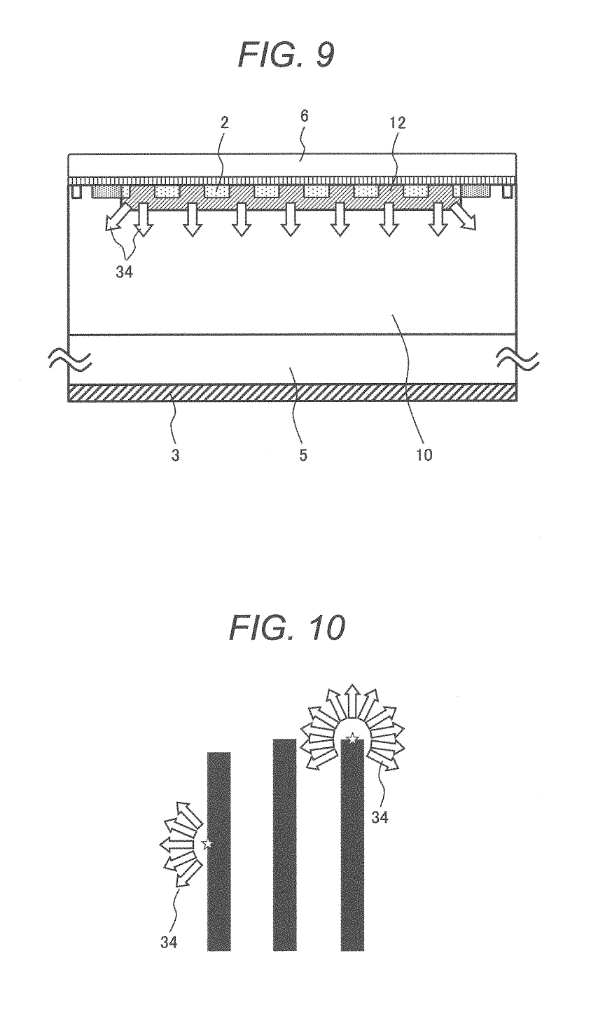

FIG. 9 is a sectional view similar to FIG. 7 schematically showing the aspect of electric current flowing in an SiC-SBD. Electric current 34 flowing from an anode electrode 6 into an SiC-SBD expands abruptly in the lateral direction from the border of an active region and a periphery region and hence the electric current concentrates in an n-type impurity region 12 at the border and the electric current density increases locally. Here, when a periphery region expands because a JTE structure is provided similarly to Embodiment 1, current concentration increases. Actually, according to studies by the present inventors, the breakdown portion of an SiC-SBD caused by surge current concentrates at the border of an active region and a periphery region.

FIG. 10 shows the aspect of current concentration at an anode-side pattern of an n-type impurity region where a Schottky junction is formed. When the pattern of a Schottky junction that is a conductive region is linear, at the end of the linear pattern, the planar spread angle of the electric current 34 is considerably larger than 180 degrees and the degree of the current concentration is particularly large at a border. At apart of a linear pattern along the longitudinal direction in contrast, the planar spread angle of the electric current 34 is smaller than the end of the linear pattern and hence the degree of the current concentration also is smaller than the end of the linear pattern in a boundary region. The degree of the current concentration, however, is larger than a linear pattern on both the sides of which other linear patterns are arranged.

In FIG. 10, when a Schottky junction having an annular pattern according to Embodiment 1 is arranged around a linear pattern, the electric current concentrating at the end of the linear pattern in FIG. 10 is shared by the annular pattern and hence the current concentration to the end of the linear pattern is relaxed. Likewise, the current concentration to the part of the linear pattern along the longitudinal direction at a border is also relaxed. Further, since an annular pattern is a continuous pattern with no ends, the pattern of a Schottky junction at the border of an active region and a periphery region is equivalent to the part of the linear pattern along the longitudinal direction over the whole circumference of the border. As a result, the current concentration in the annular pattern itself is suppressed. Consequently, local current concentration in the active region is relaxed and hence the surge current ruggedness of an SiC-SBD improves.

In Embodiment 1, an annular pattern has a substantially quadrangular shape including the corners of which are arc-shaped. Parallel two sides of the quadrilateral extend in the longitudinal direction in which the ends of a plurality of linear patterns are aligned. Further, other parallel two sides of the quadrilateral are parallel with the linear patterns belonging to both the ends of the line-and-space pattern comprising the linear patterns. Since the corners are arc-shaped, current concentration to the corners of the substantially quadrangular annular pattern is relaxed.

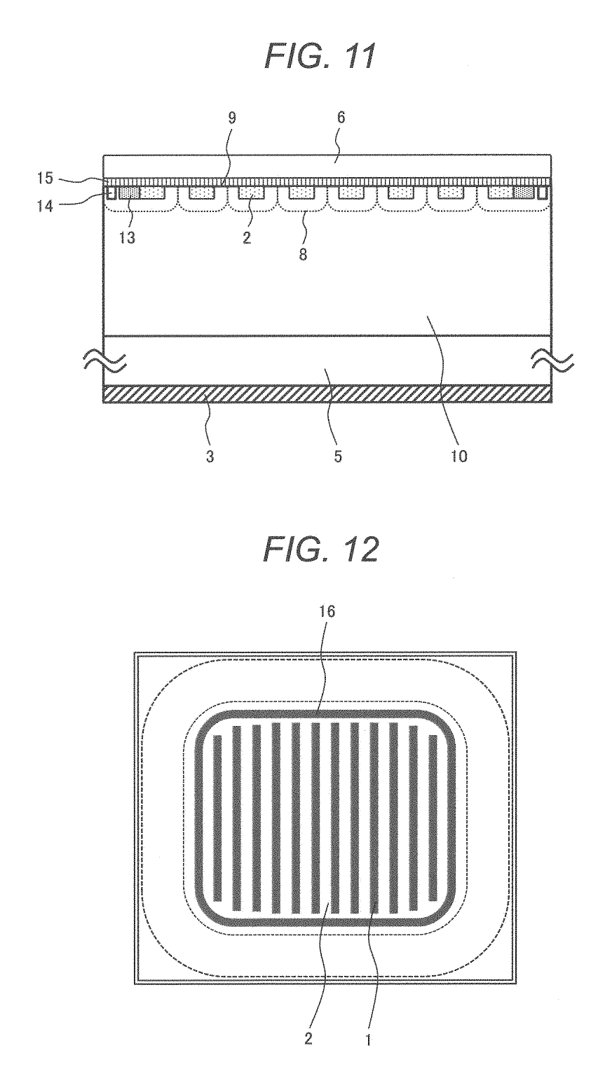

In this way, in Embodiment 1, linear patterns are arranged at the center part of an active region and consequently the controllability of JBS effect improves as follows. In a JBS structure generally, when voltage is applied in the reverse direction, a depletion layer 8 extending from a p-type impurity region 2 covers a Schottky junction 9 over an n-type impurity region as shown in FIG. 11 (sectional view showing depletion layers in a JBS structure). As a result, the electric field of the Schottky junction is relaxed and hence the leak current of an SBD having a JBS structure is smaller than a simple SBD (refer to FIG. 4). The distance between adjacent p-type impurity regions 2 is set at a dimension of allowing the depletion layers to pinch off so that the depletion layers 8 may cover the Schottky junctions 9 in this way. The linear pattern facilitates process design allowing the intervals between patterns to be controlled equally and has a high mass-production stability. Consequently, patterns of allowing depletion layers to pinch off can be formed with a high degree of accuracy and at a high yield. Here, in Embodiment 1, the number of annular patterns for relaxing current concentration is three and is smaller than the number of linear patterns. As a result, the influence of forming annular patterns on the controllability of JBS effect is small.

In Embodiment 1, the p-type impurity region 2, 17, together with the n-type impurity region 1, is in contact with the Schottky electrode 15 and the JBS effect as stated above is exhibited when the Schottky junction is biased reversely but the p-type impurity region 2, 17 does not contribute to the conduction of electric current and is a nonconductive region when the Schottky junction is biased forwardly. That is, the impurity concentration of the p-type impurity region 2, 17 (an example is described later) and the accompanying contact state between the p-type impurity region 2, 17 and the Schottky electrode 15 are set so that a minority carrier may scarcely be injected from the p-type impurity region 2, 17. As a result, in Embodiment 1, forward current in the range up to a surge current flows substantially only by a majority carrier. Consequently, according to Embodiment 1, the increase of recovery loss and conductivity degradation caused by the minority carrier can be suppressed even while surge current ruggedness improves. Further, according to Embodiment 1, surge current ruggedness can improve by adding Schottky junction of an annular pattern even when surge current ruggedness improvement effect by conductivity modulation like MPS does not exist.

In Embodiment 1, an impurity concentration is set on the basis of performance desired as an SBD and the dimension of each pattern is set at an appropriate dimension allowing a JBS effect to be obtained in response to the set impurity concentration. In Embodiment 1, for example, when a withstand voltage is 3.3 kV, the impurity concentrations of a p-type impurity region 2 and an n-type impurity region 1 are about 9×10¹⁸ atoms/cm³ and about 3×10¹⁶ atoms/cm ³ in terms of a peak value respectively. In correspondence to such impurity concentrations, both the width (line width) of a linear pattern of the p-type impurity region 2 and the width (line width) of an annular pattern of a p-type impurity region 17 are 2.7 μm and both the width of a linear pattern of the n-type impurity region 1, namely a Schottky junction, and the width of an annular pattern of an n-type impurity region 16, namely a Schottky junction, are 1.3 μm. Under such pattern dimensions, the area ratio of a second active region (19 in FIG. 8) including an annular pattern to a whole active region is set at not larger than 1%. As a result, to provide an annular pattern scarcely influences the characteristics such as V_{F} and leak current other than surge current ruggedness.

Here, in Embodiment 1, the pattern configuration on the anode side is changed from a conventional configuration but other configurations including the vertical structure and various kinds of used materials are similar to conventional ones. Consequently, a manufacturing process similar to the conventional example in FIG. 7 can be adopted for example. As a result, the surge current ruggedness of an SiC-SBD can improve without incurring cost increase.

In the case of not forming an n-type impurity region 11 in FIG. 8 as a modified example of Embodiment 1 too, a Schottky junction having an annular pattern according to Embodiment 1 can be applied. On this occasion, a Schottky junction comprises an n⁻-type SiC epitaxial layer 10 and a Schottky electrode 15.

### Embodiment 2

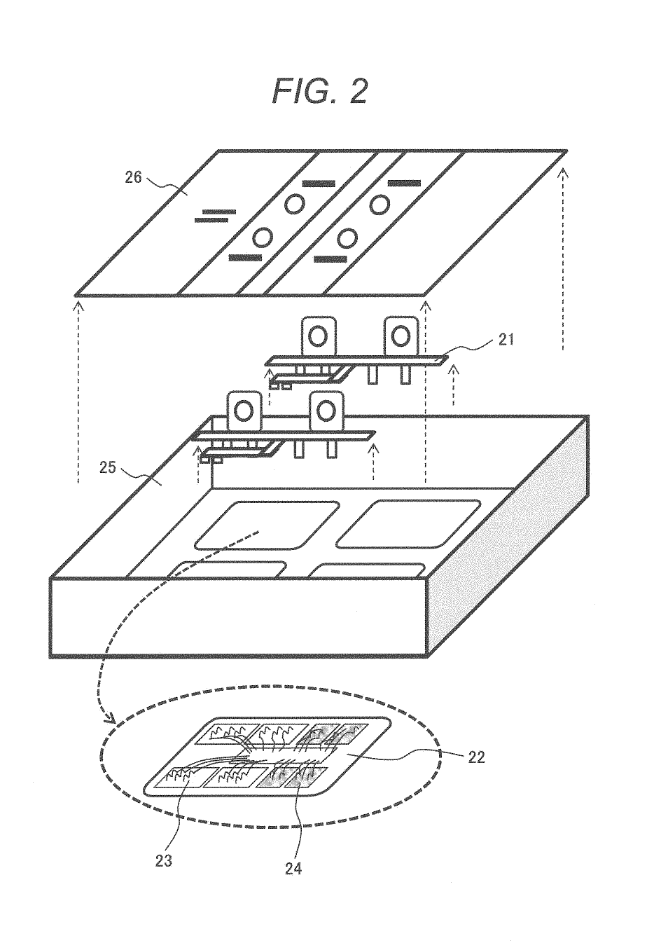

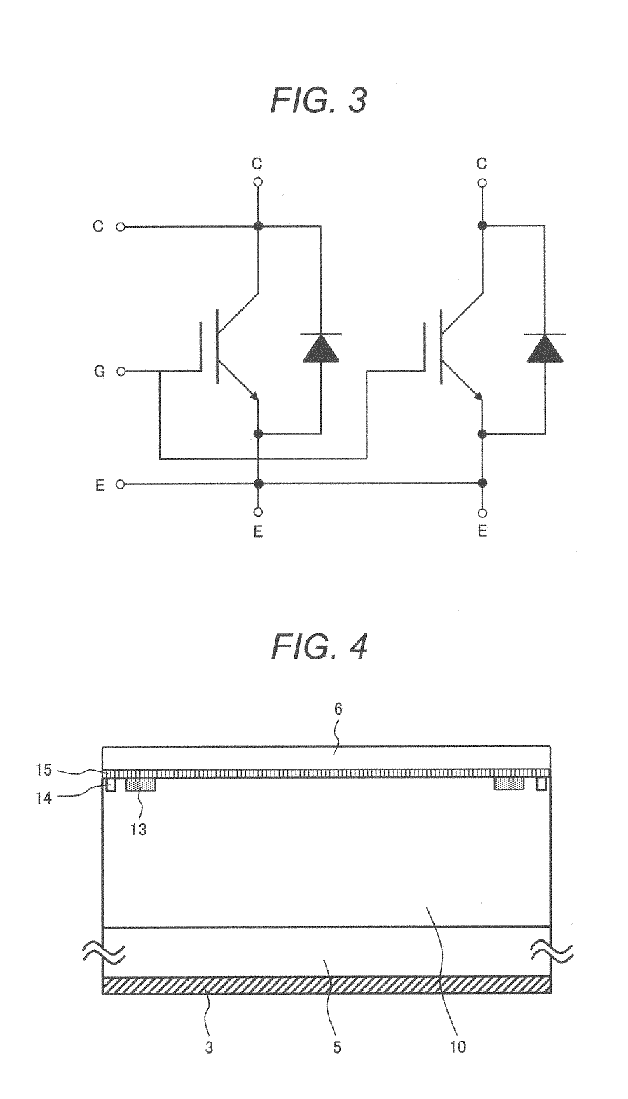

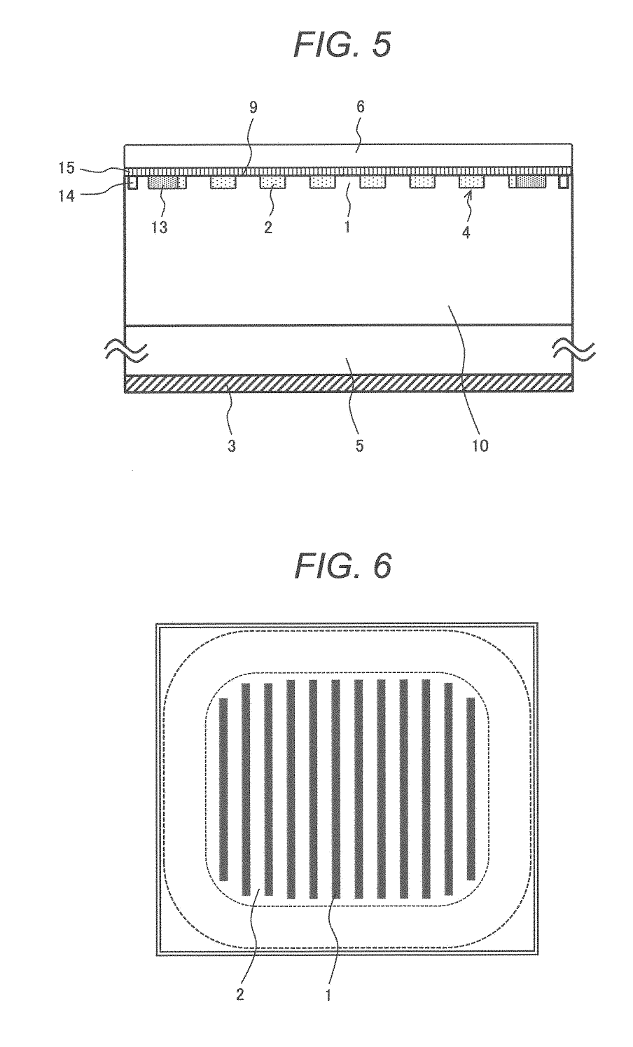

FIG. 2 is an assembly diagram showing a configuration of a power semiconductor module according to Embodiment 2 of the present invention. Further, FIG. 3 shows a circuit configuration of a power semiconductor module according to Embodiment 2. The power semiconductor module is an SiC hybrid module incorporating an IGBT (Insulated Gate Bipolar Transistor) of silicon that is a switching element and an SiC-SBD of Embodiment 1 as power semiconductor elements.

As shown in FIG. 2, a plurality of IGBTs 23 and a plurality of SiC-SBDs 24 are connected over an insulation wiring substrate 22. The IGBTs 23 and the SiC-SBDs 24 are connected to each other in anti-parallel over the insulation wiring substrate. A plurality of such insulation wiring substrates 22 are stored in a resin case 25. Here, each of the insulation wiring substrates may adhere to a heat dissipation metal substrate adhered to a resin case bottom. A wiring electrode 21 having external terminals is connected to the insulation wiring substrates. Consequently, the wiring electrode 21 is also stored in the resin case. The interior of the resin case 25 is filled with a gel-like resin not shown in FIG. 2 in order to protect or insulate members in the resin case and a lid 26 is attached. The external terminals of the wiring electrode 21 are taken out to the exterior of the resin case 25 through the lid 26. Here, the numbers of the IGBTs, the SiC-SBDs, and the insulation substrates are set in accordance with current characteristics and voltage characteristics desired as a power semiconductor module.

As shown in FIG. 3, a plurality of circuits in each of which an IGBT and an SiC-SBD are connected in anti-parallel are arranged by wiring in a resin case so that the circuits can be used by parallel connection and external terminals (G: gate terminal, E: emitter terminal, C: collector terminal) for connecting external wires are taken out. That is, a power semiconductor module according to the present embodiment constitutes one arm circuit and has a so-called 1-in-1 configuration. Consequently, an SiC-SBD provided in a power semiconductor module functions as a free wheeling diode.

In this way, according to Embodiment 1, the increase of recovery loss and conductivity degradation caused by a minority carrier can be suppressed while surge current ruggedness improves. Consequently, according to Embodiment 2, the loss of a power semiconductor module can be reduced and the reliability of a power semiconductor module can improve.

Meanwhile, as an SiC-SBD, not only Embodiment 1 but also the embodiments described below can be applied. Further, as a switching element, not only an IGBT of silicon but also an IGBT of SiC, a MOSFET of silicon or SiC, or the like may be used.

Further, as a power semiconductor module having an arm circuit comprising a semiconductor switching element and an SiC-SBD according to an embodiment of the present invention, a so-called transfer mold type power semiconductor module in which a lead frame on which a power semiconductor element is mounted is molded by a resin may also be adopted.

### Embodiment 3

FIG. 12 shows a planar pattern of a power semiconductor element according to Embodiment 3 of the present invention. The power semiconductor element according to Embodiment 3 is an SiC-SBD having a JBS structure similarly to Embodiment 1 and FIG. 12 shows a planar pattern on the anode side similarly to FIG. 1. Points different from Embodiment 1 are explained hereunder.

In Embodiment 3, as shown in FIG. 12, unlike Embodiment 1, the number of an n-type impurity region 16, namely the number of an annular pattern of Schottky junction, is only one. According to Embodiment 3, not only surge current ruggedness improves similarly to Embodiment 1 but also the changes of a chip size, the shape and dimension of a pattern, and the like from the conventional ones corresponding to desired characteristics can be minimized. Consequently, the increase of difficulty in design and the increase of cost of a power semiconductor element can be avoided even when an annular pattern is added.

Further, Embodiment 3 is suitable for an SiC-SBD of a relatively low withstand voltage. According to studies by the present inventors, in the case of an SiC-SBD of a low withstand voltage, when the insulation distance from an active end to a chip end is short, namely the area of a periphery region is small, and the proportion of the periphery region to an active region reduces, current concentration in a boundary region is relatively mild. Consequently, a large current concentration relaxation effect is obtained even in the case of only one annular pattern.

### Embodiment 4

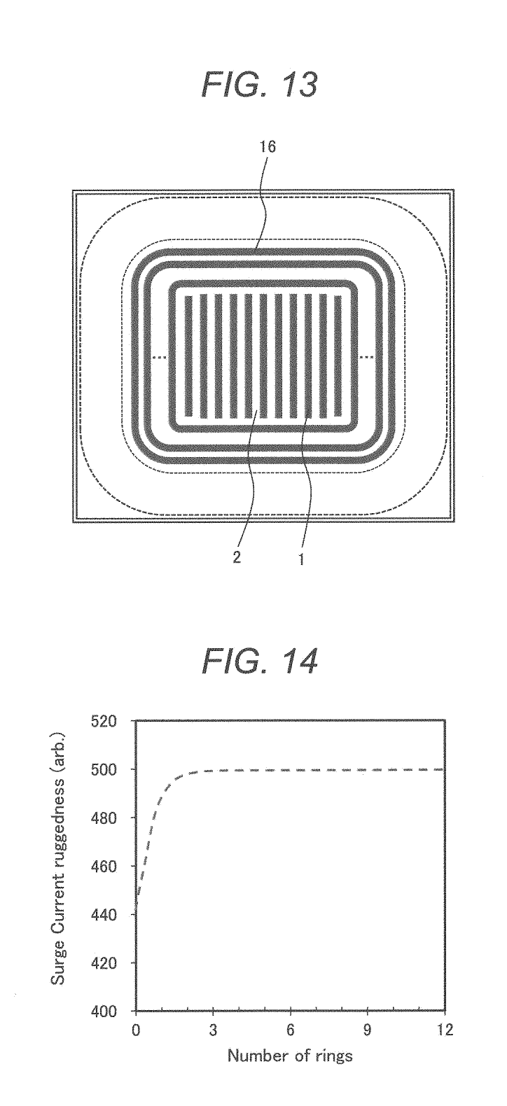

FIG. 13 shows a planar pattern of a power semiconductor element according to Embodiment 4 of the present invention. The power semiconductor element according to Embodiment 4 is an SiC-SBD having a JBS structure similarly to Embodiments 1 and 3 and FIG. 13 shows a planar pattern on the anode side similarly to FIGS. 1 and 12. Points different from Embodiments 1 and 3 are explained hereunder.

In Embodiment 4, as shown in FIG. 13, unlike Embodiments 1 and 3, the number of n-type impurity regions 16, namely annular patterns of Schottky junction, is 12. Here, in FIG. 13, some of the repeated annular patterns are omitted for the sake of simplicity.

According to Embodiment 4, the insulation distance from an active end to a chip end is long and the surge current ruggedness of an SiC-SBD of a high withstand voltage in which the proportion of a periphery region to an active region is large can improve. Further, a sufficient surge current ruggedness is obtained even when the current capacity and the current density of an SiC-SBD increase.

FIG. 14 shows an example of relationship between a number of annular patterns and a surge current ruggedness. In FIG. 14, the horizontal axis represents a number of annular patterns and the vertical axis represents an index representing a magnitude of surge current ruggedness. The value 0 (zero) on the horizontal axis means that no annular pattern exists and only linear patterns exist. Here, FIG. 14 is based on a withstand voltage of 3.3 kV.

As shown in FIG. 14, although the effect of improving surge current ruggedness is obtained even when only one annular pattern exists, arrangement of a plurality of annular patterns is particularly effective and the effect is maximum when the number is three to twelve in the example of FIG. 14. Here, according to studies by the present inventors, as long as the number of annular patterns is twelve, surge current ruggedness can improve without fail even when some variations exist.

Here, the number of annular patterns is desirably larger than three in the case of a high withstand voltage exceeding 3.3 kV. In contrast, in the case of a withstand voltage lower than 3.3 kV, the number of annular patterns maybe smaller than three and can be one similarly to Embodiment 3 stated earlier.

### Embodiment 5

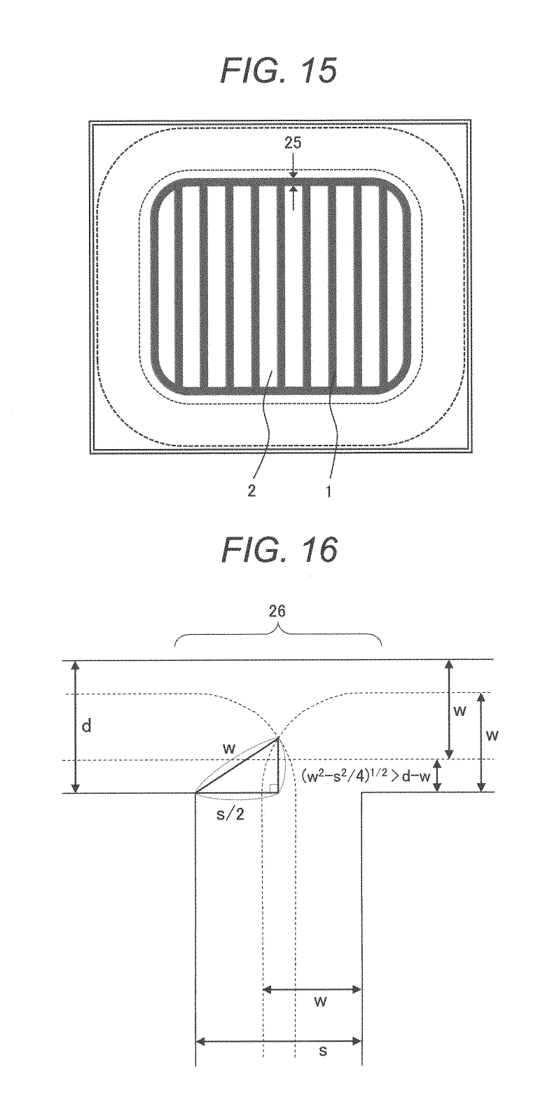

FIG. 15 shows a planar pattern of a power semiconductor element according to Embodiment 5 of the present invention. The power semiconductor element according to Embodiment 5 is an SiC-SBD having a JBS structure similarly to Embodiments 1, 3, and 4 and FIG. 15 shows a planar pattern on the anode side similarly to FIGS. 1, 12, and 13. Points different from Embodiments 1, 3, and 4 are explained hereunder.

In Embodiment 5, as shown in FIG. 15, unlike Embodiments 1, 3, and 4, an annular pattern is connected to both the ends of each of linear patterns. Consequently, the pattern of Schottky junction in Embodiment 5 is in the state of no ends as a whole. As a result, electric current flowing from the ends in an active region on the anode side toward a periphery region on a cathode side scarcely concentrates at the ends of the linear patterns and flows equally over the whole circumference of the annular pattern. As a result, current concentration at the border of the active region and the periphery region is relaxed and hence surge current ruggedness improves.

Further, although the width of a linear pattern and the width of an annular pattern are identical in Embodiments 1, 3, and 4, the width 25 of an annular pattern is restricted as follows in Embodiment 5.

FIG. 16 shows a connecting part of an annular pattern and a linear pattern. The broken lines in FIG. 16 represent the ends of depletion layers respectively. In a JBS structure, as stated earlier, when reverse voltage is applied, a Schottky junction is covered with a depletion layer extending from a p-type impurity region and hence the electric field of the Schottky junction is relaxed. In this way, the width s of a linear pattern is set at a value not more than twice the growth width w of a depletion layer so that a Schottky junction may be covered with a depletion layer. Further, at a connecting part 26 of an annular pattern and a linear pattern, when the vicinity of the center of the connecting part 26 remotest from an adjacent p-type impurity region boundary is covered all over with a depletion layer, there is the relationship of the expression (1) among the width d of the annular pattern, the growth width w of the depletion layer, and the width s of the linear pattern of an n-type impurity region.

(w²-s²/4)^{1/2}>d-w (1)

Consequently, the width d of an annular pattern is subjected to restriction represented by the expression (2).

d<w+(w²-s²/4)^{1/2} (2)

According to the restriction of the expression (2), the width d of an annular pattern is smaller than the width s of a linear pattern in some cases.

Here, as a modified example of Embodiment 5, a concentric annular pattern may be provided so as to surround an annular pattern according to Embodiment 5. As a result, the surge current ruggedness of an SiC-SBD of a high withstand voltage having a large area ratio of a periphery region can improve.

### Embodiment 6

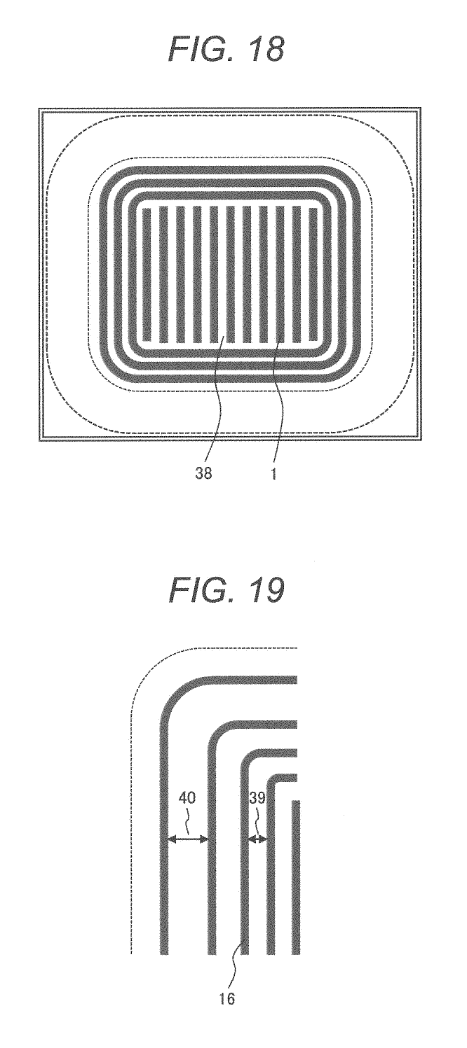

In Embodiment 6 according to the present invention, a p-type impurity region constituting a JBS structure and a Schottky electrode in Embodiments 1 and 3 to 5 stated earlier make ohmic contact. As a result, the impurity concentration of the p-type impurity region is about 1×10²⁰ atoms/cm³ in terms of a peak value and is higher than those of Embodiments 1 and 3 to 5 stated earlier. A pattern on an anode side is similar to Embodiments 1 and 3 to 5 stated earlier and an example is shown in FIG. 18. The pattern in this example is similar to Embodiment 1 (FIG. 1) and has a Schottky junction having three concentric annular patterns at the border of a main part of an active region having a plurality of linear patterns and a periphery region. In this example, aluminum (Al) is used as the p-type impurity in a p-type impurity region 38, the impurity concentration is set at about 1×10²⁰ atoms/cm³ in terms of a peak value, and the p-type impurity region 38 and a Schottky electrode (refer to 15 in FIG. 8) are in contact with each other in an ohmic state or a nearly ohmic state.

In Embodiment 6, since a Schottky junction of an annular pattern is provided and holes that are a minority carrier are injected from the p-type impurity region 38 during forward bias, conductivity modulation occurs and hence surge current ruggedness improves. Here, in the case of SiC, a band gap is larger than Si, hence a built-in voltage V_{b1} by p-n junction is as large as about 3 V, and the p-n junction, namely the p-type impurity region, is nonconductive until the voltage of an SiC-SBD exceeds the built-in voltage. That is, holes are not injected from the p-type impurity region and hence the p-type impurity region does not contribute to the improvement of surge current. In contrast, in Embodiment 6, the Schottky junction of an annular pattern relaxes current concentration at a stage before a sufficient number of holes are injected from a p-type impurity region and contributes to the improvement of surge current ruggedness. Further, when the voltage of the SiC-SBD rises and an excessive electric current flows, a high surge current ruggedness is obtained by the combined effect of the relaxation of current concentration by the annular pattern and conductivity modulation by injecting a sufficient number of holes from the p-type impurity region.

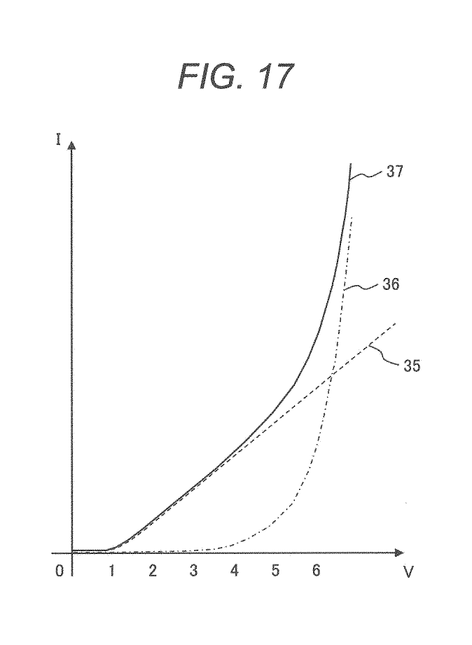

FIG. 17 shows a current/voltage (IV) characteristic of an SiC-SBD according to Embodiment 6. Here, in FIG. 17, the IV characteristic 37 of an SiC-SBD according to Embodiment 6 is shown with the solid line. Further, for comparison, an IV characteristic 35 of a simple SiC-SBD not having a JBS structure (refer to FIG. 4) and an IV characteristic 36 of an SiC-PN diode (hereunder referred to as “SiC-PND”) are shown with the broken line and the alternate long and short dash line respectively.

As the IV characteristic 35 shows, in the case of the simple SiC-SBD, electric current I flows when voltage V exceeds a relatively small value such as about 1 V and it shows a linear, namely ohmic IV characteristic. In contrast, in the case of the SiC-PND, when V is a large value such as slightly less than 3 V and exceeds V_{b1} of p-n junction, resistance lowers by conductivity modulation caused by injecting a minority carrier and hence I increases rapidly as the IV characteristic 36 shows. In an SiC-SBD according to Embodiment 6, a simple SiC-SBD part and an SiC-PND part are combined in the manner of being connected in parallel and hence it shows the IV characteristic 37 formed by combining the IV characteristic 35 and the IV characteristic 36. In the IV characteristic 37 of Embodiment 6, when voltage V is larger than about 4 V, electric current flowing in a p-type impurity region, namely an SiC-PND part, increases. On this occasion, in Embodiment 6, an electric current about twice a forward rated current flows. Here, an electric current twice a rated current corresponds to the maximum value of an allowable repetitive current that is a general SOA (Safe Operation Area) condition. That is, in Embodiment 6, a p-type impurity region is nonconductive to an electric current not larger than the electric current twice the rated current. As a result, in the state of an ordinary operation where an SiC-SBD is used in the range of a rated current, the injection of a minority carrier from a p-type impurity region is suppressed. As a result, in Embodiment 6, recovery loss does not increase and conductivity degradation is prevented while surge current ruggedness improves by conductivity modulation caused by injecting a minority carrier from a p-type impurity region.

### Embodiment 7

FIG. 19 shows a planar pattern of a power semiconductor element according to Embodiment 7 of the present invention. The power semiconductor element according to Embodiment 7 is an SiC-SBD having a JBS structure similarly to Embodiments 1 and 3 to 6 and FIG. 19 shows parts of annular patterns on an anode side. Points different from Embodiments 1 and 3 to 6 are explained hereunder.

As shown in FIG. 19, in Embodiment 7, the widths of annular patterns of a p-type impurity region, which annular patterns are located between annular patterns of Schottky junction, increase from the inside toward the outside and the area ratio of the p-type impurity region that is nonconductive at least when an electric current not more than twice a rated current flows increases. Here, the width of the annular patterns of Schottky junction is constant. As a result, current densities, at the ends of linear patterns of Schottky junction in the longitudinal direction and at linear patterns located at the border of a first active region (18 in FIG. 8) where a plurality of linear patterns are arranged and a periphery region, reduce. As a result, surge current ruggedness improves.

In Embodiment 7, since the number of annular patterns of Schottky junction is four, the number of annular patterns of a p-type impurity region is three. When the widths of the three annular patterns of the p-type impurity region are defined as I₁, I₂, and I₃ (I₁<I₂<I₃) from the innermost circumference, the width I₁ of the annular pattern 39 of the p-type impurity region located at the innermost circumference is set so as to be equal to the width (I) of the linear patterns of the p-type impurity region (I₁=I) and the width (I₃) of the annular pattern 40 of the p-type impurity region located at the outermost circumference is set at a width four times I (I₃=4I). The width (I₂) of the other annular pattern of the p-type impurity region is set by proportional allotment. Here, the number of annular patterns of the p-type impurity region is not limited to three and may also be two or more.

### Embodiment 8

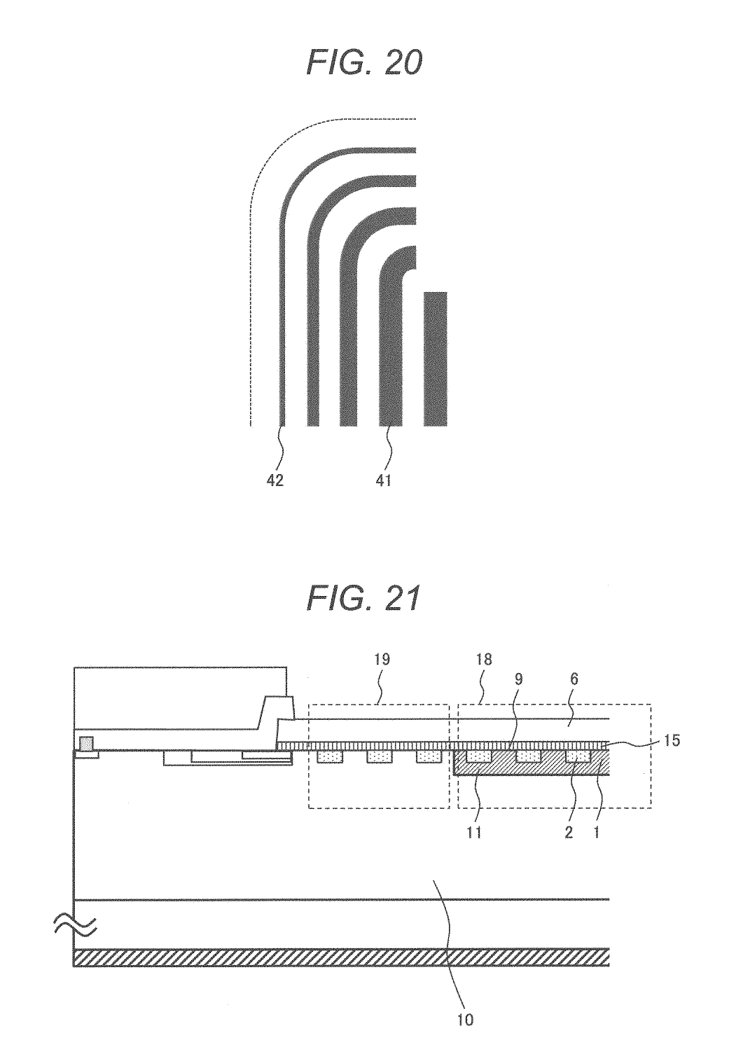

FIG. 20 shows a planar pattern of a power semiconductor element according to Embodiment 8 of the present invention. The power semiconductor element according to Embodiment 8 is an SiC-SBD having a JBS structure similarly to Embodiments 1 and 3 to 7 and FIG. 20 shows parts of annular patterns on an anode side. Points different from Embodiments 1 and 3 to 7 are explained hereunder.

As shown in FIG. 20, in Embodiment 8, the widths of annular patterns of an n-type impurity region, namely Schottky junction, reduce from the inside toward the outside and the area ratio of an n-type impurity region in which electric current flows reduces. Here, the width of annular patterns of a p-type impurity region is constant. As a result, current densities at the ends of linear patterns of Schottky junction in the longitudinal direction and at linear patterns located at the border of a first active region where a plurality of linear patterns are arranged and a periphery region reduce.

As a result, surge current ruggedness improves.

In Embodiment 8, since the number of annular patterns of Schottky junction is four, the number of annular patterns of a p-type impurity region is three. When the widths of four annular patterns of a n-type impurity region are defined as s₁, s₂, s₃, and s₄ (s₁>s₂>s₃>s₄) from the innermost circumference, the width s₁ of an annular pattern 41 of the n-type impurity region located at the innermost circumference is set so as to be equal to the width (s) of a linear pattern of the n-type impurity region (s₁=s) and the width (s₄) of an annular pattern 42 of the n-type impurity region located at the outermost circumference is set at a width ¼ times s (s₄=s/4). The widths (s₂ and s₃) of the other annular patterns of the n-type impurity region are set by proportional allotment. Here, the number of annular patterns of Schottky junction is not limited to four and may also be two or more.

### Embodiment 9

FIG. 21 is a sectional view in the vertical direction similar to FIG. 8, showing a partial vertical structure of a power semiconductor element according to Embodiment 9 of the present invention. The power semiconductor element according to Embodiment 9 is an SiC-SBD having a JBS structure similarly to Embodiments 1 and 3 to 8. Points different from Embodiments 1 and 3 to 8 are explained hereunder.

As shown in FIG. 21, in Embodiment 9, unlike the configuration of the vertical cross section shown in FIG. 8, an n-type impurity region 11 (current dispersion layer) is provided only in a first active region 18 in a first active region 18 including Schottky junction of linear patterns and the second active region 19 including Schottky junction of annular patterns. Consequently, the Schottky junction of linear patterns in the first active region 18 comprises the n-type impurity region 11 and a Schottky electrode 15 and the Schottky junction of annular patterns in the second active region 19 comprises an n⁻-type SiC epitaxial layer 10 and the Schottky electrode 15.

As a result, the current density of the second active region 19 including the Schottky junction of annular patterns, namely the outer periphery of the first active region 18 having linear patterns, lowers. As a result, current densities, at the ends of linear patterns of Schottky junction in the longitudinal direction and at linear patterns located at the border of a first active region where a plurality of linear patterns are arranged and a periphery region, reduce. As a result, surge current ruggedness can improve.

Meanwhile, the present invention is not limited to the aforementioned embodiments and includes various modified examples. For example, the aforementioned embodiments are explained in detail for explaining the present invention clearly and the present invention is not necessarily limited to the cases having all the explained configurations. Further, with regard to a part of the configuration of each of the embodiments, another configuration can be added, deleted, and replaced.

For example, although an aforementioned SiC-SBD is an SBD of an n-type, the present invention can also apply to an SBD Schottky diode of a p-type in which the conductivity types of the semiconductor regions are reversed, namely an n-type is changed to a p-type and a p-type is changed to an n-type. Further, although an aforementioned SiC-SBD is a so-called SBD of a planar type, the present invention can also apply to an SBD of a trench type. On this occasion, for example, a JBS structure is formed at the bottom of a trench formed in an SiC semiconductor layer and Schottky junctions of linear and annular patterns are formed at a convex part between trenches. Furthermore, although a power semiconductor element in the aforementioned embodiments is an SiC-SBD of a single body, the present invention can also apply to a power semiconductor element formed by combining an SiC-SBD with another element such as a switching element.

### REFERENCE SIGNS LIST

1 . . . n-type impurity region,

2 . . . p-type impurity region,

3 . . . Cathode electrode,

4 . . . p-n junction,

5 . . . n⁺-type SiC substrate,

6 . . . Anode electrode,

8 . . . Depletion layer,

9 . . . Schottky junction,

10 . . . n⁺-type SiC epitaxial layer,

11 . . . n-type impurity region,

12 . . . n-type impurity region,

14 . . . Channel stopper,

15 . . . Schottky electrode,

16 . . . n-type impurity region,

17 . . . p-type impurity region,

18 . . . First active region,

19 . . . Second active region,

20 . . . Periphery region,

21 . . . Wiring electrode,

22 . . . Insulation wiring substrate,

23 . . . IGBT,

24 . . . SiC-SBD,

31 . . . p-type impurity region,

32 . . . p-type impurity region,

33 . . . p-type impurity region,

38 . . . p-type impurity region,

39 . . . Annular pattern,

40 . . . Annular pattern,

41 . . . Annular pattern,

42 . . . Annular pattern.

1. A power semiconductor element having a Schottky barrier diode comprising silicon carbide, wherein:
the Schottky barrier diode has an active region and a periphery region located around the active region;
the active region includes
a first electrode,
a first semiconductor region of a first conductivity type configuring a first Schottky junction having a plurality of linear patterns between the first electrode and the first semiconductor region,
a second semiconductor region of a second conductivity type adjacent to the first Schottky junction and connected to the first electrode, and
a second electrode connected to the first semiconductor region;
the periphery region includes the first semiconductor region and the second electrode;
at the border of the active region and the periphery region, a second Schottky junction comprising the first electrode and the first semiconductor region and having at least one annular pattern surrounding the linear patterns is provided and the second semiconductor region is adjacent to the second Schottky junction and is connected to the first electrode; and
the first and second Schottky junctions are conductive parts and the second semiconductor region is a nonconductive part in a forward bias state.

2. The power semiconductor element according to claim 1, having a plurality of the annular patterns arranged concentrically.

3. The power semiconductor element according to claim 1, wherein the annular pattern is endless.

4. The power semiconductor element according to claim 3, wherein the annular pattern has a linear part parallel with the direction in which a plurality of ends of the linear patterns are aligned, a linear part parallel with the longitudinal direction of the linear patterns, and arc-shaped corners.

5. The power semiconductor element according to claim 1, wherein the first semiconductor region has:
a substrate region with which the second electrode is in contact;
a first semiconductor layer having an impurity concentration lower than the substrate region; and
a second semiconductor layer having an impurity concentration higher than the first semiconductor layer, being adjacent to the first semiconductor layer, and configuring the first and second Schottky junctions with the first electrode.

6. The power semiconductor element according to claim 1, wherein a forward current flows only through a majority carrier.

7. The power semiconductor element according to claim 2, wherein the number of the annular patterns is three or more.

8. The power semiconductor element according to claim 1, wherein a plurality of ends of the linear patterns connect with the annular pattern.

9. The power semiconductor element according to claim 1, wherein the second semiconductor region is a nonconductive part in the state where an electric current not more than twice a rated current flows.

10. The power semiconductor element according to claim 9, wherein the second semiconductor region is a conductive part in the state where an electric current more than twice a rated current flows.

11. The power semiconductor element according to claim 2, wherein the second semiconductor region has a plurality of annular patterns arranged alternately with the concentric annular patterns of the second Schottky junction at the border.

12. The power semiconductor element according to claim 11, wherein the widths of the annular patterns of the second semiconductor region increase from an inner circumference toward an outer circumference.

13. The power semiconductor element according to claim 11, wherein the widths of the annular patterns of the second Schottky junction decrease from an inner circumference toward an outer circumference.

14. The power semiconductor element according to claim 1, wherein:
the first semiconductor region has
a substrate region with which the second electrode is in contact,
a first semiconductor layer having an impurity concentration lower than the substrate region, and
a second semiconductor layer having an impurity concentration higher than the first semiconductor layer and being adjacent to the first semiconductor layer;
the first Schottky junction comprises the first electrode and the second semiconductor layer; and
the second Schottky junction comprises the first electrode and the first semiconductor layer.

15. A power semiconductor module having an arm circuit configured by connecting a semiconductor switching element to a Schottky barrier diode in antiparallel, wherein:
the Schottky barrier diode comprises silicon carbide and has an active region and a periphery region located around the active region;
the active region includes
a first electrode,
a first semiconductor region of a first conductivity type configuring a first Schottky junction having a plurality of linear patterns between the first electrode and the first semiconductor region,
a second semiconductor region of a second conductivity type adjacent to the first Schottky junction and connected to the first electrode, and
a second electrode connected to the first semiconductor region;
the periphery region includes the first semiconductor region and the second electrode;
at the border of the active region and the periphery region, a second Schottky junction comprising the first electrode and the first semiconductor region and having at least one annular pattern surrounding the linear patterns is provided and the second semiconductor region is adjacent to the second Schottky junction and is connected to the first electrode; and
the first and second Schottky junctions are conductive parts and the second semiconductor region is a nonconductive part in a forward bias state.
